(19) United States
(12) Patent Application Publication
(10) Pub. No.: US 2020/0263293 A1
(43) Pub. Date: Aug. 20, 2020

(54) APPARATUS FOR PRODUCING POLYCRYSTALLINE SILICON AND POLYCRYSTALLINE SILICON

(71) Applicant: Shin-Etsu Chemical Co., Ltd., Tokyo (JP)

(72) Inventors: Tetsuro Okada, Niigata (JP); Naruhiro Hoshino, Niigata (JP); Masahiko Ishida, Niigata (JP)

(73) Assignee: Shin-Etsu Chemical Co., Ltd., Tokyo (JP)

(21) Appl. No.: 16/787,274

(22) Filed: Feb. 11, 2020

(30) Foreign Application Priority Data
Feb. 14, 2019 (JP) 2019-024192

(51) Int. Cl. C23C 16/24; C01B 33/035; C23C 16/458; C23C 16/50

(52) U.S. Cl. CPC C23C 16/24; C23C 16/50; C23C 16/458; C01B 33/035

(57) ABSTRACT

An apparatus for producing polycrystalline silicon by the Siemens method, includes: a carbon-made core wire holder 14 holding a silicon core wire 13; an electrode portion 10 energizing the core wire holder 14, the electrode portion 10 having a top end 18 in contact with a bottom end of the core wire holder 14; and a first screwing section provided 17a only around a lower part of the core wire holder 14 to be fixed to the electrode portion 10, wherein the core wire holder 14 has a contact surface with the top end 18 of the electrode portion 10, the contact surface being lower in electric resistance than an area of the first screwing section 17a to be fastened.

### TECHNICAL FIELD

The present invention relates to an apparatus for producing the polycrystalline silicon by the Siemens method using a carbon-made core wire holder and to polycrystalline silicon produced by the same.

### BACKGROUND ART

The Siemens method is known as a method for producing polycrystalline silicon which is a raw material of single crystal silicon for semiconductors or silicon for manufacturing solar cells. The Siemens method is a method in which a source gas containing chlorosilane is brought into contact with a heated silicon core wire, and thereby polycrystalline silicon is vapor-phase grown on a surface of the silicon core wire using a CVD (Chemical Vapor Deposition) method.

In a reaction furnace for vapor-phase growth of polycrystalline silicon with the Siemens method, two vertical silicon core wires and one horizontal silicon core wire are assembled in a gate shape (so-called torii in Japanese) inside a space composed of an upper structure called a bell jar and a lower structure called a base plate (bottom plate). Both ends of two silicon core wires are fixed to a pair of metal electrodes arranged on the base plate via a pair of carbon core wire holders. This configuration is disclosed in, for example, Patent Literature 1 (Japanese Patent Application Laid-Open Publication No. 2009-256191).

The electrode penetrates the base plate in a state that an insulator is sandwiched therebetween to be connected to another electrode through wiring or connected to a power source arranged outside the reaction furnace. The electrode, the base plate and the bell jar are cooled by refrigerant such as water to prevent deposition of polycrystalline silicon during vapor-phase growth, or to prevent heavy metal contamination in polycrystalline silicon causable by metal temperature rise.

The electrode and the carbon-made core wire holder are fixed by fitting or the like. The carbon-made core wire holder may be directly connected to the electrode or may be connected via a structure called an adapter for purpose of suppressing consumption of the electrode. Carbon is often used as a material of the adapter, and the adapter is fixed by fitting into the electrode or the like.

High-purity silicon is vapor-phase grown on the silicon core wire by conducting an electric current from the electrode to the silicon core wire through the core wire holder, and then supplying a mixed gas of trichlorosilane and hydrogen as a source gas from a gas nozzle into the reaction furnace while heating a surface of the silicon core wire to a temperature range of about 900° C. to 1200° C. in a hydrogen atmosphere by Joule heat. At this time, silicon rod also deposits on a side of the carbon-made core wire holder as a diameter of silicon rod increases, and gradually becomes integrated with the carbon-made core wire holder. Further, since electric resistance decreases as silicon rod grows, it is necessary to increase current corresponding to a diameter of silicone rod until a desired diameter is formed in order to maintain a surface of silicon rod at reaction temperature.

Currently, an electric current to be applied to silicon rod is 2000 A to 4000 A when reaction is terminated. Since heat dissipation from a surface of silicon rod increases as a diameter of silicon rod increases, it is necessary to add electric energy to silicon rod corresponding to heat dissipation in order to maintain temperature of 900° C. to 1200° C. required for reaction. Therefore, a carbon-made core wire holder which connects a metal electrode and a polycrystalline silicon rod to each other is required to have a structure and a connection method that can withstand increasing electric current and weight.

When current density of a carbon-made core wire holder and an electrode increases, a local energizing portion may be created depending on a contact state between an electrode and a carbon-made core wire to cause heavy metal contamination in polycrystalline silicon due to high temperature beyond assumption. Further, when an electrode and a carbon-made core wire are set in an unstable connection state or a contact surface therebetween becomes unstable due to increasing weight of silicon rod, an electric discharge occurs between a carbon-made core wire holder and an electrode to cause damage to both, resulting in that heavy metal contamination and/or carbon contamination in polycrystalline silicon may be caused.

According to the background art, for example, as disclosed in Patent Literature 2 (Japanese Patent Application Laid-Open Publication No. 05-213697) and Patent Literature 3 (Japanese Patent Application Laid-Open Publication No. 2011-195439), an electrode and a carbon-made core wire holder are often connected by fitting. Such connection in this manner has an advantage of easiness of setting, but a state of a contact surface between an electrode and a carbon-made core wire holder is unstable. That is, for example, since a kind of control corresponding to “tightening torque control” in case of connecting by screws is not applicable, it is difficult to confirm whether a surface pressure is sufficiently applied to a contact surface. Also, a contact surface itself and/or distribution of pressure applied to a contact surface may be varied due to subtle differences in shape of mutual mating surfaces or change in force applied to a carbon-made core wire holder resulting from a setting method or an imbalance in growth of a polycrystalline silicon rod. So, there are disadvantages that a contact surface and a non-contact surface are ambiguous and unstable, and further, a local energizing portion and a high temperature portion thereby are easily formed.

In the method as disclosed in Patent Literature 4 (Japanese Patent Application Laid-Open Publication No. 2010-235438), a carbon-made core wire holder is fixed to an electrode with a screw. This fixing of a carbon-made core wire holder is mechanically strong, but since a screw is made as an energizing portion, an electric discharge is easily caused when a screw is energized, and electric connection is unstable since a position of a contact surface is not controllable.

As described above, connection manners of a carbon-made core wire holder and an electrode known in the background art are not sufficient in stability of energizing surface and may cause a local high temperature portion and an electric discharge. Once in-furnace members are damaged by an electric discharge, it is extremely troublesome to set matters right. An electrode needs to be replaced with a new one, and a silicon rod is contaminated. Further, since a bell jar and a base plate are also contaminated and a hydrocarbon compound is contained as an impurity in a reaction exhaust gas to be collected and circulated, producing after a next batch is adversely affected. Therefore, it is necessary to perform cleaning up of everything more than usual.

### CITATION LIST

### Patent Literature

[Patent Literature 1] Japanese Patent Application Laid-Open Publication No. 2009-256191

[Patent Literature 2] Japanese Patent Application Laid-Open Publication No. 05-213697

[Patent Literature 3] Japanese Patent Application Laid-Open Publication No. 2011-195439

[Patent Literature 4] Japanese Patent Application Laid-Open Publication No. 2010-235438

### SUMMARY OF INVENTION

### technical Problem

The present invention is made in view of the above-mentioned problems, and an object thereof is to provide an apparatus for producing polycrystalline silicon and polycrystalline silicon produced by the apparatus, the apparatus being applied with a technique that makes stable energization between a core wire holder and an electrode portion to enable avoidance of not only damage to an electrode portion but contamination of a silicon rod.

### Solution to Problem

In order to achieve the above object, a first aspect of the present invention is an apparatus for producing polycrystalline silicon by the Siemens method, comprising: a carbon-made core wire holder holding a silicon core wire; an electrode portion energizing the core wire holder, the electrode portion having a top end in contact with a bottom end of the core wire holder; and a first screwing section provided only around a lower part of the core wire holder to be fixed to the electrode portion, wherein the core wire holder has a contact surface with the top end of the electrode portion, the contact surface being lower in electric resistance than an area of the first screwing section to be fastened.

The first screwing section may be positioned below the contact surface of the core wire holder with the top end of the electrode portion.

The apparatus for producing polycrystalline silicon may further include a second screwing section provided around an upper part of the electrode portion, wherein the first screwing section of the core wire holder and the second screwing section of the electrode portion may be fastened by an insulating nut member.

The top end of the electrode portion and the contact surface of the core wire holder with the top end of the electrode portion may be formed horizontal, respectively.

The apparatus for producing polycrystalline silicon may further include a conductive member inserted between the bottom end of the core wire holder and the top end of the electrode portion.

A second aspect of the present invention is polycrystalline silicon produced by an apparatus for producing polycrystalline silicon as above-mentioned.

### Advantageous Effects of Invention

According to the present invention, there is provided an apparatus for producing polycrystalline silicon and polycrystalline silicon produced by the apparatus, the apparatus being applied with a technique that makes stable energization between a core wire holder and an electrode portion to enable avoidance of not only damage to an electrode portion but contamination of a silicon rod.

### BRIEF DESCRIPTION OF DRAWINGS

FIG. 1 is a schematic explanatory view showing an example of a reaction furnace including a core wire holder according to the present invention;

FIG. 2 is a conceptual diagram showing a first embodiment in which a core wire holder according to the present invention is attached to an electrode portion;

FIG. 3 is a conceptual diagram showing a second embodiment in which a core wire holder according to the present invention is attached to an electrode portion; and

FIG. 4 is a conceptual diagram showing a mode in which a core wire holder is attached to an electrode portion in the background art.

### DESCRIPTION OF EMBODIMENTS

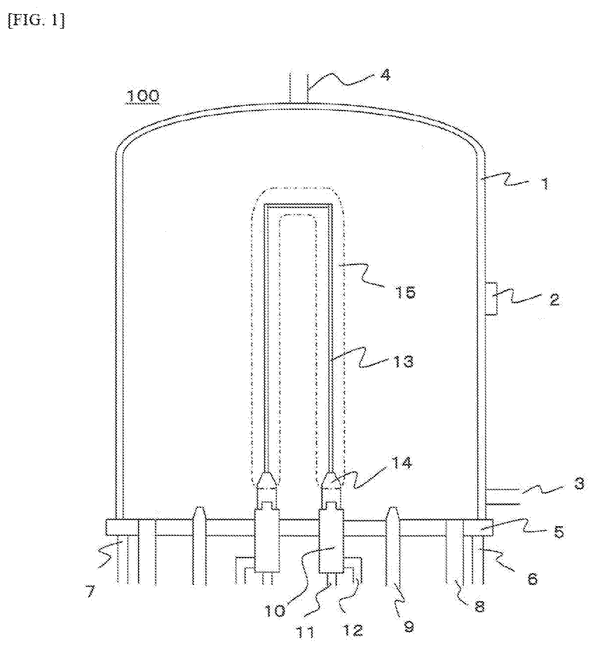

FIG. 1 is a diagram for explaining an outline of configuration of a reaction furnace of an apparatus for producing polycrystalline silicon in which a carbon-made core wire holder according to the present invention is used. A reaction furnace 100 includes an electrode portion 10 penetrating a base plate 5 provided at a lower portion of a bell jar 1 in a manner that the electrode portion 10 is insulated from the base plate 5, and a carbon-made core wire holder 14 holding a silicon core wire 13 is fixed to the electrode portion 10. The core wire holder 14 is directly joined to the electrode portion 10 or fixed by a jig (not shown) to be connected to the electrode portion 10. Most of electric current supplied from the electrode portion 10 is carried to the core wire holder 14 through a contact surface between the core wire holder 14 and the electrode portion 10. Polycrystalline silicon 15 is deposited on the silicon core wire 13 by reaction of a source gas.

In FIG. 1, besides the above-mentioned, there are shown an observation window 2, an inlet 3 and an outlet 4 of refrigerant for cooling the bell jar 1, an inlet 6 and an outlet 7 of refrigerant for cooling the base plate 5, an inlet 11 and an outlet 12 of refrigerant for cooling the electrode portion 10, a supply nozzle 9 of a source gas, and an outlet 8 of a reaction exhaust gas.

There is no particular limitation in a manner that the core wire holder 14 is fixed to the electrode portion 10. However, because of easiness in manufacturing in accordance with standards such as JIS (the Japanese Industrial Standards), it is preferable to be screwed using a screw. In addition, a tool may be used for fixing. For example, a desired pressure (a contact surface pressure) may be applied to a contact surface between a bottom end of the core wire holder 14 and a top end of the electrode portion 10 by using a torque wrench. In this case, by controlling torque value, it is easy to suppress dispersion of contact surface pressures between batches. Further, a conductive member in a low impurity level, such as a carbon-made sheet, may be inserted between the core wire holder 14 and the electrode portion 10 (that is, the contact surface between the bottom end of the core wire holder 14 and the top end of the electrode portion 10) to support electric connection.

After the core wire holder 14 is fixed to the electrode portion 10, the reaction furnace 100 is sealed by the bell jar 1 in a bell shape, and air in the reaction furnace 100 is replaced with nitrogen and then replaced with hydrogen. Thereafter, when an electric current is supplied from the electrode portion 10 to the silicon core wire 13 through the core wire holder 14, a surface of the silicon core wire 13 is heated to about 900° C. to 1200° C. by Joule heat. In such circumstance, a source gas containing trichlorosilane and hydrogen is sprayed, resulting in that high-purity polycrystalline silicon 15 is deposited on the surface of the silicon core wire 13.

In order to maintain a surface temperature of the polycrystalline silicon 15 at a temperature necessary for reaction, it is necessary to increase the electric current as the polycrystalline silicon 15 grows. For this reason, a mechanical load increases due to an increase in weight of the silicon rod to the core wire holder 14 and the contact surface between the core wire holder 14 and the electrode portion 10, and an electric load also increases due to an increase in current density. In this case, if the contact surface serving as the energization surface is formed horizontal, the contact surface pressure increases as the weight of the polycrystalline silicon 15 to allow the contact resistance to decrease, so that the contact surface becomes more electrically stable. Therefore, it is preferable that the top end of the electrode portion 10 and a contact surface of the core wire holder 14 with the top end of the electrode portion 10 are formed horizontal, respectively.

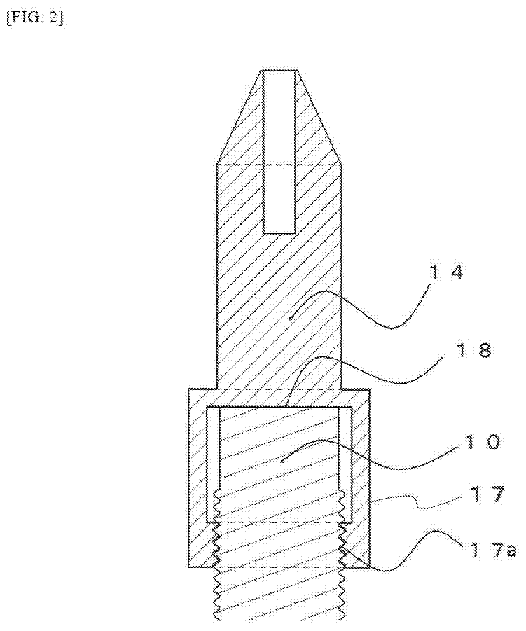

FIG. 2 is a conceptual diagram that explains a first embodiment of the core wire holder 14 provided in the apparatus for producing polycrystalline silicon by the Siemens method according to the present invention. As shown in FIG. 2, a bottom end of the core wire holder 14 is in contact with the top end 18 of the electrode portion 10 energizing the core wire holder 14. In addition, the core wire holder 14 is provided with a fixing part 17 further extending downwardly below the bottom end of the core wire holder 14, and the fixing part 17 has a screwing section 17a around a lower part thereof. The screwing section 17a is positioned below the contact surface between the bottom end of the core wire holder 14 and the top end of the electrode portion 10. It is noted that the screwing section 17a is provided only on the lower part of the core wire holder 14.

The contact surface between the bottom end of the core wire holder 14 and the top end 18 of the electrode portion 10 is formed to be lower in electric resistance than an area where the screwing section 17a is fastened. Thus, almost of the electric current flowing to the silicon core wire 13 flows through the contact surface between the bottom end of the core wire holder 14 and the top end 18 of the electrode portion 10. Thereby, it is possible to obtain a stable connection both structurally and electrically without particularly using an insulating jig.

That is, a material having a low electric resistivity such as copper or SUS (Steel Use Stainless) is generally used for the electrode portion 10, and the electric resistivity is much lower than that of the carbon-made core wire holder 14. Therefore, by positioning the top end 18 (a contact surface) of the electrode portion 10 higher than the screwing section 17a, a path via the contact surface becomes lower in electric resistance than a path via the screwing section 17a. As a result, most of the electric current flows to the silicon core wire 13 through the contact surface (the top end 18), while a current amount through the screwing section 17a may be almost negligible.

The configuration of the core wire holder 14 according to the present invention is not limited to that shown in FIG. 2.

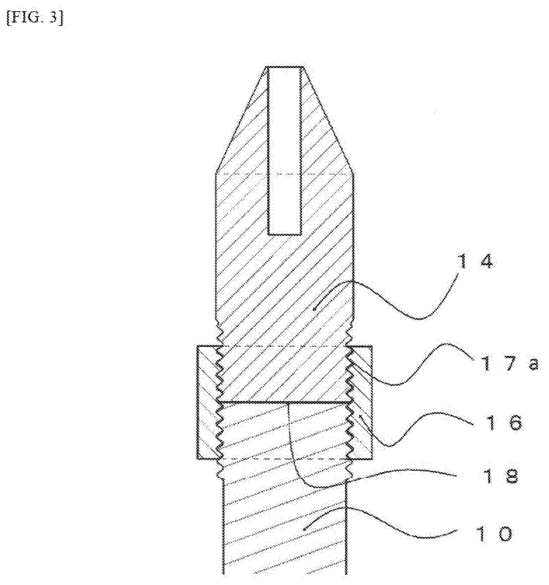

FIG. 3 is a conceptual diagram that explains a second embodiment of the core wire holder 14 provided in the apparatus for producing polycrystalline silicon by the Siemens method according to the present invention. In the second embodiment shown in FIG. 3, the core wire holder 14 is similar to the first embodiment as shown in FIG. 2 in that a bottom end thereof is in contact with the top end 18 of the electrode portion 10 energizing the core wire holder 14, the core wire holder 14 has a screwing section 17a in use for fixing to the electrode portion 10, and a contact surface between the bottom end of the core wire holder 14 and the top end 18 of the electrode portion 10 is formed to be lower in electric resistance than an area where the screwing section 17a is fastened. On the other hand, the core wire holder 14 is different from the first embodiment in that a screwing section 17a is also provided on an upper part of the electrode portion 10, and the screwing sections 17a of the core wire holder 14 and the electrode portion 10 are fastened by a nut member 16 made of an insulator as a fixing jig.

Even in such an embodiment, since no electric current flows through the nut member 16 made of an insulator, almost of the current flows to the silicon core wire 13 through the contact surface (the top end 18).

By using the core wire holders 14 as above according to the present invention, it is possible to keep stable energization while ensuring a sufficient fixing force. This therefore leads to results that local high temperature and occurrence of electric discharge are suppressed and contamination of polycrystalline silicon by impurities such as heavy metals and carbon is prevented.

In Patent Literature 1, a section corresponding to the screwing section 17a of the present invention is provided entirely over a side surface of a core wire holder, and therefore an electric discharge, etc. is likely to occur accidentally in such uneven-shaped section. In contrast to this, according the present invention, the screwing section 17a is provided only on the lower part of the core wire holder 14, and therefore it is possible to achieve suppression in occurrence of such electric discharge, etc.

In Patent Literature 2, a core wire holder is formed in a so-called fitting type, and therefore an electric discharge, etc. is likely to occur accidentally due to instability in fixing to an electrode. In contrast to this, according to the present invention, the core wire holder 14 is fixed by the screwing section 17a, and therefore it is possible to achieve suppression in occurrence of such electric discharge, etc.

In Patent Literature 3, a core wire holder is also formed in a so-called fitting type, and therefore an electric discharge, etc. is likely to occur accidentally due to instability in fixing to an electrode. In contrast to this, according to the present invention, the core wire holder 14 is fixed by the screwing section 17a, and therefore it is possible to achieve suppression in occurrence of such electric discharge, etc.

In Patent Literature 4, at first sight, a core wire holder looks similar to the core wire holder 14 according to the second embodiment of the present invention. However, there is formed in a stepped columnar shape having an outer diameter of a lower part larger than an outer diameter of an upper part, and therefore an electric discharge, etc. is likely to occur accidentally due to electric current flowing through a screwing section in an uneven shape. In contrast to this, according to the present invention, the core wire holder 14 is fixed by the screwing section 17a, and therefore it is possible to achieve suppression in occurrence of such electric discharge, etc.

### EXAMPLES

Examples are described hereinafter. Polycrystalline silicon was deposited on the silicon core wire 13 in the reaction furnace 100 of the apparatus for producing polycrystalline silicon by the Siemens method until a pair of polycrystalline silicon rods were grown to 125 kg to 200 kg. After completion of the reaction, a pair of polycrystalline silicon rods were collected, and then, it was confirmed whether abnormality such as a discharge mark or discoloration due to abnormal heat generation occurred on the electrode portion 10 and the core wire holder 14.

### Example 1

The core wire holder 14 shown in FIG. 2 was fixed to the electrode portion 10 with a torque of 80 Nm. Two batches of deposition reaction were carried out until a pair of polycrystalline silicon rods were grown to about 125 kg. No abnormality such as a discharge mark or discoloration was confirmed in any batch.

### Example 2

The core wire holder 14 shown in FIG. 2 was fixed to the electrode portion 10 with a torque of 80 Nm. Three batches of deposition reaction were carried out until a pair of polycrystalline silicon rods were grown to about 200 kg. No discharge mark was confirmed in any batch. But, the core wire holder 14 was in part bonded to the electrode portion 10 at a rate of 16.7%.

### Example 3

The core wire holder 14 shown in FIG. 2 was fixed to the electrode portion 10 with a torque of 80 Nm in a manner that a sheet-like member made of high purity graphite (Na<0.05, Cu<0.08, Fe and Ni<0.1, Zn<0.1) was inserted between the core wire holder 14 and the electrode portion 10. Three batches of deposition reaction were carried out until a pair of polycrystalline silicon rods were grown to about 200 kg. No abnormality such as a discharge mark or discoloration was confirmed in any batch.

### Comparative Example 1

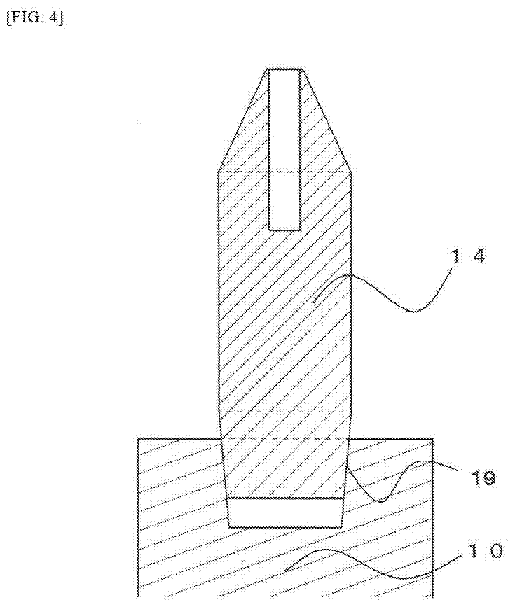

The core wire holder 14 shown in FIG. 4 was fixed to the electrode portion 10 by twisting and fitting. Two batches of deposition reaction were carried out until a pair of polycrystalline silicon rods were grown to about 125 kg. No discharge mark was confirmed in any batch. But, the electrode portion 10 at a rate of 4.2% became discolored to black on a contact surface with the carbon-made core wire holder 14, and the carbon-made core wire holder 14 was in part bonded to the electrode portion 10 at a rate of 29.2%.

### Comparative Example 2

The core wire holder 14 shown in FIG. 4 was fixed to the electrode portion 10 by twisting and fitting. Three batches of deposition reaction were carried out until a pair of polycrystalline silicon rods were grown to about 200 kg. A discharge mark was confirmed on a contact surface with the core wire holder 14 in the electrode portion 10 at a rate of 16.7%. Moreover, the electrode portion 10 at a rate of 25.0% became discolored to black on a contact surface with the core wire holder 14, and the core wire holder 14 was in part bonded to the electrode portion 10 at a rate of 41.7%.

### INDUSTRIAL APPLICABILITY

According to the present invention, there is provided an apparatus for producing polycrystalline silicon and polycrystalline silicon produced by the apparatus, the apparatus being applied with a technique that makes stable energization between a core wire holder and an electrode portion to enable avoidance of not only damage to an electrode portion but contamination of a silicon rod.

### REFERENCE SIGNS LIST

1 . . . bell jar;
2 . . . observation window;
3 . . . inlet of refrigerant (with respect to bell jar);
4 . . . outlet of refrigerant (with respect to bell jar);
5 . . . base plate;
6 . . . inlet of refrigerant (with respect to base plate);
7 . . . outlet of refrigerant (with respect to base plate);
8 . . . outlet of reaction exhaust gas;
9 . . . supply nozzle of source gas;
10 . . . electrode portion;
11 . . . inlet of refrigerant (with respect to electrode portion);
12 . . . outlet of refrigerant (with respect to electrode portion);
13 . . . silicon core wire;
14 . . . core wire holder;
15 . . . polycrystalline silicon;
16 . . . nut member;
17 . . . fixing part;
17a . . . screwing section;
18 . . . top end of electrode portion;
19 . . . fitting part; and
100 . . . reaction furnace.

1. An apparatus for producing polycrystalline silicon by the Siemens method, comprising:
a carbon-made core wire holder holding a silicon core wire;
an electrode portion energizing the core wire holder, the electrode portion having a top end in contact with a bottom end of the core wire holder; and
a first screwing section provided only around a lower part of the core wire holder to be fixed to the electrode portion,
wherein the core wire holder has a contact surface with the top end of the electrode portion, the contact surface being lower in electric resistance than an area of the first screwing section to be fastened.

2. The apparatus for producing polycrystalline silicon according to claim 1, wherein the first screwing section is positioned below the contact surface of the core wire holder with the top end of the electrode portion.

3. The apparatus for producing polycrystalline silicon according to claim 1, further comprising a second screwing section provided around an upper part of the electrode portion,
wherein the first screwing section of the core wire holder and the second screwing section of the electrode portion are fastened by an insulating nut member.

4. The apparatus for producing polycrystalline silicon according to claim 1, wherein the top end of the electrode portion and the contact surface of the core wire holder with the top end of the electrode portion are formed horizontal, respectively.

5. The apparatus for producing polycrystalline silicon according to claim 1, further comprising a conductive member inserted between the bottom end of the core wire holder and the top end of the electrode portion.

6. Polycrystalline silicon produced by an apparatus for producing polycrystalline silicon according to claim 1.
